(19) United States
(12) Patent Application Publication
(10) Pub. No.: US 2013/0183625 A1
(43) Pub. Date: Jul. 18, 2013

(54) PATTERNED GRAPHENE FABRICATION METHOD

(71) Applicants: Chien-Min SUNG, New Taipei City (TW); I-Chiao Lin, Taipei City (TW); Hung-Cheng Lin, New Taipei City (TW)

(72) Inventors: Chien-Min SUNG, New Taipei City (TW); I-Chiao Lin, Taipei City (TW); Hung-Cheng Lin, New Taipei City (TW)

(21) Appl. No.: 13/444,504

(22) Filed: Apr. 11, 2012

(30) Foreign Application Priority Data
Jan. 17, 2012 (TW) 101101662

(51) Int. Cl. G03F 7/20; B82Y 40/00

(52) U.S. Cl. 430/323; 977/847

(57) ABSTRACT

A method for fabricating patterned graphene structures, which adopts a photolithographic etching process to fabricate patterned graphene structures, comprises steps: providing a substrate; forming a catalytic layer on the substrate; forming a carbon layer on the catalytic layer; heating the carbon layer to a synthesis temperature to form a graphene layer. A photolithographic etching process is performed on the catalytic layer before formation of the carbon layer. Alternatively, a photolithographic etching process is performed on the carbon layer before heating. Alternatively, a photolithographic etching process is performed on the graphene layer after heating. Compared with the laser etching process, the photolithographic etching process is suitable to fabricate large-area patterned graphene structures and has advantages of high productivity and low cost.

### FIELD OF THE INVENTION

The present invention relates to a graphene fabrication method, particularly to a patterned graphene fabrication method.

### BACKGROUND OF THE INVENTION

Graphene is an allotrope of carbon, which is a material formed of 2-dimensional 6-carbon hexagonal cells. Graphene features transparency, high electric conductivity, high thermal conductivity, high strength-to-weight ratio, and fine ductility. Therefore, the academia and industry have invested a lot of resources in introducing graphene into the existing electronic element processes and anticipate that graphene can promote the overall performance thereof. At present, graphene is mainly applied to transistors, electrodes of lithium batteries, photosensors, and transparent electrodes of touchscreens, LED, solar cells, etc.

A U.S. Pat. Pub. No. 2010/0237296 disclosed a graphene fabrication method, which reduces a single-layer graphite oxide into graphite in a high boiling point solvent. Firstly, disperse a single-layer graphite oxide in water to form a dispersion liquid. Next, add a solvent to the dispersion liquid to form a solution. The solvent is selected from a group consisting of N-methlypyrrolidone, ethylene glycol, glycerin, dimethlypyrrolidone, acetone, tetrahydrofuran, acetonitrile, dimethylformamide, amine, and alcohol. Next, heat the solution to a temperature of about 200° C. Then, obtain single-layer graphite with a purification process. A U.S. Pat. Pub. No. 2010/0323113 disclosed a graphene synthesis method, which maintains a hydrocarbon compound at a temperature of 40-1,000° C. to implant carbon atoms into a substrate made of a metal or an alloy. With decrease of temperature, carbon deposits and diffuses out of the substrate to form graphene layers.

A U.S. Pat. Pub. No. 2011/0102068 disclosed a graphene-based device and a method for using the same. The graphene-based device comprises a laminate structure, a first electrode, a second electrode, and a dopant island. The laminate structure includes a conductive layer, an insulating layer and a graphene layer. The conductive layer is electrically coupled to the graphene layer via the insulating layer. The first and second electrodes are respectively electrically coupled to the graphene layer. The dopant island is electrically coupled to an exposed surface of the graphene layer, and the exposed surface is disposed between the first and second electrodes. The graphene layer is fabricated with an ex-foliation process or a chemical vapor deposition process.

For some applications, such as touchscreens or LED, the transparent electrodes need specified patterns or structures. Conventionally, the patterns or structures are fabricated with laser etching after the graphene layer has been done. However, laser etching is time-consuming, especially for high-definition patterns. Further, the laser etching apparatuses are expensive. Therefore, patterning graphene layers with laser etching has disadvantages of low efficiency and high cost.

### SUMMARY OF THE INVENTION

The primary objective of the present invention is to overcome the conventional problem that laser etching of graphene layers has disadvantages of low efficiency and high cost.

To achieve the abovementioned objective, the present invention proposes a patterned graphene fabrication method, which comprises steps: providing a substrate, forming a catalytic layer on the substrate, coating a carbon layer on the catalytic layer, photolithographically etching the carbon layer to form a patterned carbon layer, and heating the patterned carbon layer to a synthesis temperature to obtain a patterned graphene layer.

To achieve the abovementioned objective, the present invention proposes a patterned graphene fabrication method, which comprises steps: providing a substrate, forming a catalytic layer on the substrate, photolithographically etching the catalytic layer to form a patterned catalytic layer, forming on the patterned catalytic layer a carbon layer including a patterned area covering the patterned catalytic layer and a non-patterned area covering the substrate, heating the carbon layer to a synthesis temperature to make the patterned area of the carbon layer form a patterned graphene layer.

To achieve the abovementioned objective, the present invention proposes a patterned graphene fabrication method, which comprises steps: providing a substrate, forming a catalytic layer on the substrate, forming a carbon layer on the catalytic layer, heating the carbon layer to a synthesis temperature to form a graphene layer, photolithographically etching the graphene layer to form a patterned graphene layer.

Compared with the conventional technologies, the patterned graphene fabrication method of the present invention has the following advantages:
1. The present invention patterns the carbon layer of graphene layer with a photolithographic etching process, which is much more efficient than the laser etching process. Therefore, the method of the present invention has high productivity and is suitable to fabricate large-size patterned graphene layers.
2. The apparatuses of photolithographic etching are easy to acquire with a lower cost than that of the laser etching apparatuses. Therefore, the method of the present invention can fabricate patterned graphene layers with a lower cost.

### BRIEF DESCRIPTION OF THE DRAWINGS

FIGS. 1A-1F are sectional views schematically showing the process of a patterned graphene fabrication method according a first embodiment of the present invention;

FIG. 2 is a top view of the patterned graphene layer according to the first embodiment of the present invention;

FIGS. 3A-3G are sectional views schematically showing the process of a patterned graphene fabrication method according a second embodiment of the present invention;

FIG. 4 is a top view of the patterned graphene layer according to the second embodiment of the present invention;

FIGS. 5A-5G are sectional views schematically showing the process of a patterned graphene fabrication method according a third embodiment of the present invention; and

FIGS. 6A-5F are sectional views schematically showing the process of a patterned graphene fabrication method according a fourth embodiment of the present invention.

### DETAILED DESCRIPTION OF THE PREFERRED EMBODIMENTS

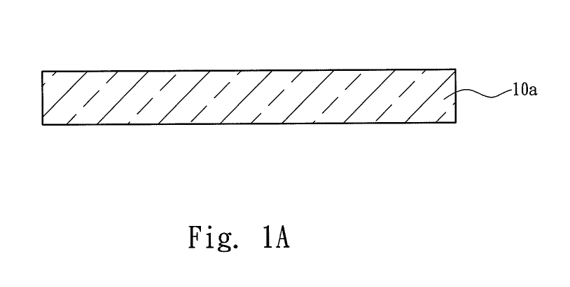

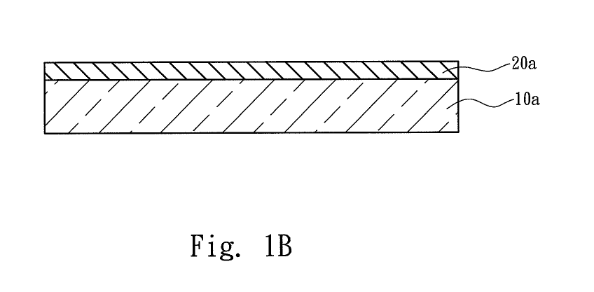

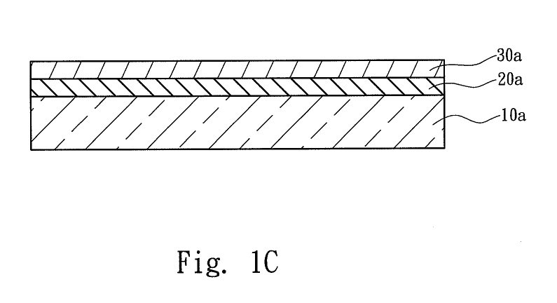

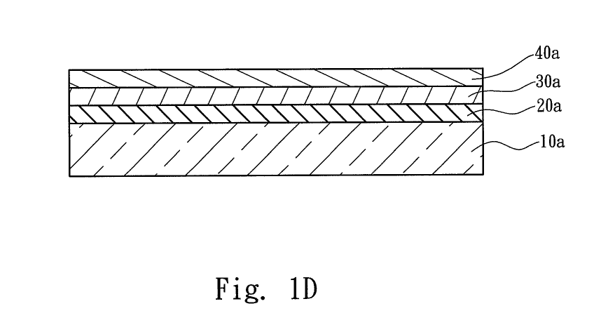

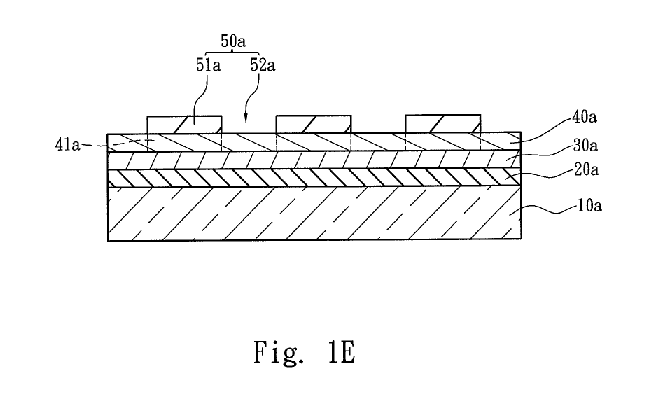

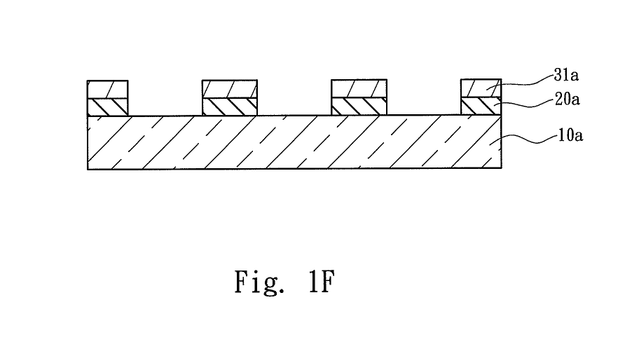

The present invention pertains to a patterned graphene fabrication method. Refer to FIGS. 1A-1F sectional views schematically showing a patterned graphene fabrication method according a first embodiment of the present invention. Firstly, provide a substrate 10a. In this embodiment, the substrate 10a is made of a material immiscible with carbon. The substrate 10a may be made of a metallic material or a ceramic material, such as copper, aluminum, silicon dioxide, aluminum oxide, or silicon carbide. The present invention does not constrain that the substrate 10a must be made of the abovementioned materials. In the present invention, the substrate 10a can be made of any material, which does not form a solid solution with carbon, i.e. does not form a homogeneous phase with carbon. Next, as shown in FIG. 1B, form a catalytic layer 20a on the substrate 10a with an evaporation deposition process or a PVD (Physical Vapor Deposition) process. The catalytic layer 20a is made of iron, cobalt, nickel, manganese, or an alloy of the abovementioned metals. Next, as shown in FIG. 1C, form a carbon layer 30a on the catalytic layer 20a with a deposition process. The deposition process may be a spin-coating process, a sputtering process, or an evaporation deposition process. The carbon layer 30a is made of graphite or a carbon-containing polymer. The carbon-containing polymer is selected from a group of consisting of acrylic resins, phenol formaldehyde resins, epoxy resins, and polymers containing long chains or hexagonal benzene rings.

After the carbon layer 30a has been formed on the catalytic layer 20a, photolithographically etch the carbon layer 30a. As shown in FIG. 1D, form a photoresist layer 40a on the carbon layer 30a firstly. Next, sequentially perform an exposure process and a development process on the photoresist layer 40a. As shown in FIG. 1E, place a photomask 50a over the photoresist layer 40a. In this embodiment, the photoresist layer 40a is made of a negative photoresist material; the photomask 50a is a perforated structure containing a light permeable area 52a and a light impermeable area 51a. The light impermeable area 51a defines at least one sacrifice area 41a in the photoresist layer 40a. The sacrifice area 41a is below the light impermeable area 51a and bordered by dashed lines in FIG. 1E. Light is projected on the photoresist layer 40a to enable the chemical reaction and cross link of the portion of photoresist layer 40a, which is below the light permeable area 52a. A development agent is used to dissolve and remove the portion of the photoresist layer 40a, which is below the light impermeable area 51a and not illuminated by light, i.e. remove the sacrifice areas 41a. Thus, a portion of the carbon layer 30a is revealed. The selections of the negative photoresist material, the development agent, and the wavelength and intensity of the light are mature conventional technologies and will not repeat herein.

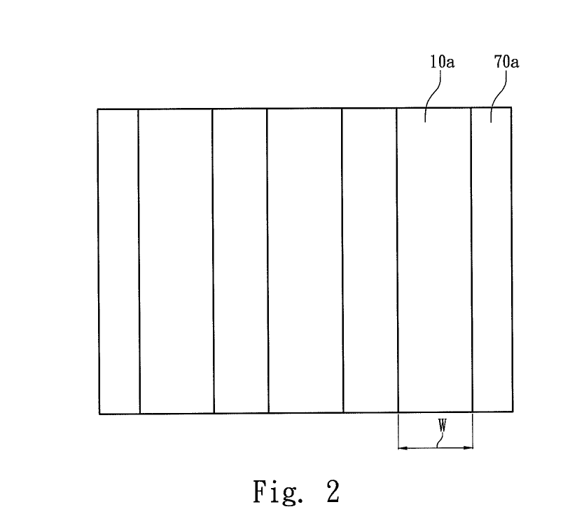

Next, perform an etching process on the carbon layer 30a to remove a portion of the carbon layer 30a corresponding to the sacrifice areas 41a. The etching process may be a chemical etching process or a reactive ion etching (RIE) process. Next, remove the photomask 50a, and use an appropriate solvent to dissolve the negative photoresist material. Thus is obtained a patterned carbon layer 31a, as shown in FIG. 1F. Then, heat the patterned carbon layer 31a to a synthesis temperature for a given interval of time to obtain a patterned graphene layer 70a. The synthesis temperature is preferably between 700 and 1,200° C. The patterned carbon layer 31a may be heated in vacuum or in an atmosphere of ammonia gas, argon, nitrogen, or a mixture of argon and hydrogen, a mixture of nitrogen and hydrogen. For the above mixtures, the volume concentration of hydrogen is preferably between 0 and 50%. In this embodiment, the given interval of time is preferably between 1 and 300 minutes. Refer to FIG. 2 a top view of the patterned graphene layer according to the first embodiment of the present invention. Preferably, each graphene structure of the patterned graphene layer 70a has a width of less than 7 μm. In this embodiment, the etching process simultaneously etches the carbon layer 30a and the catalytic layer 20a. However, the etching process may only etch the carbon layer 30a in practical fabrication processes.

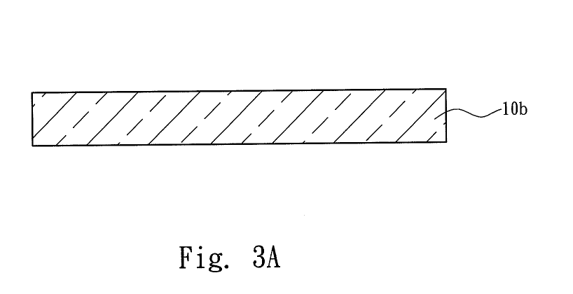

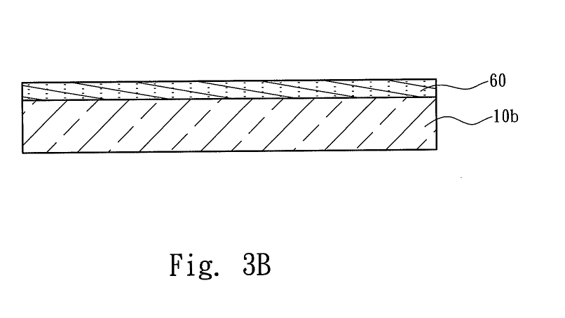

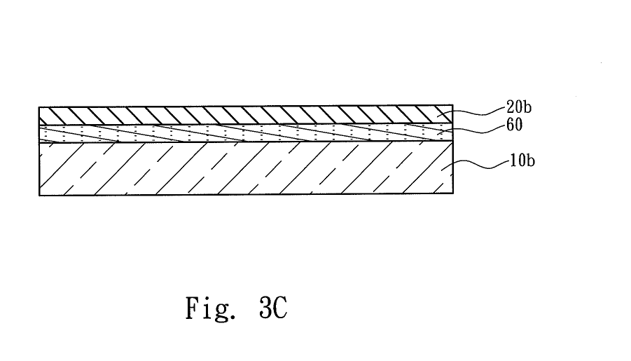

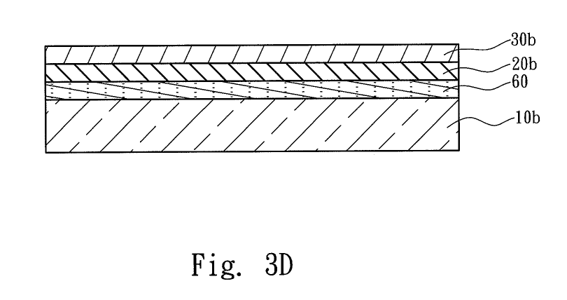

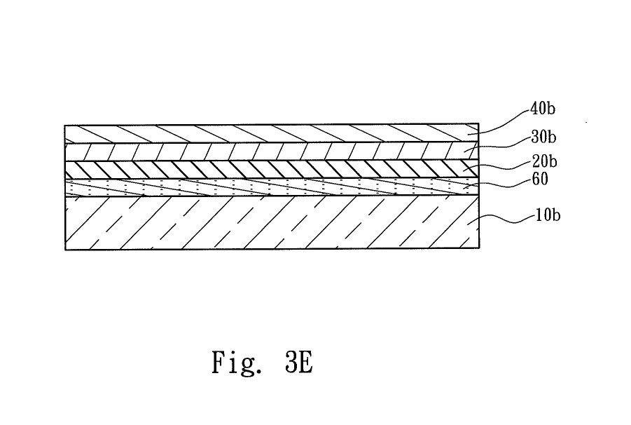

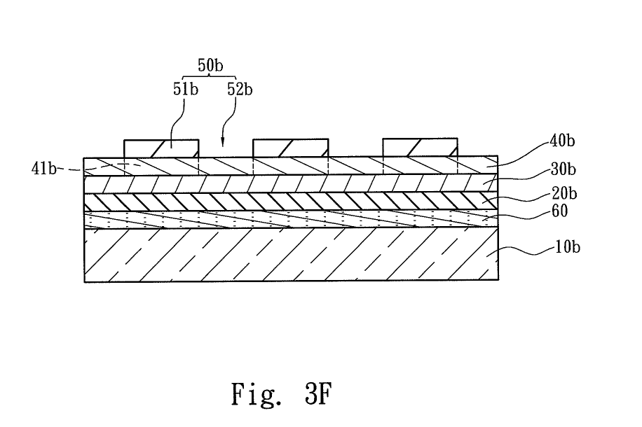

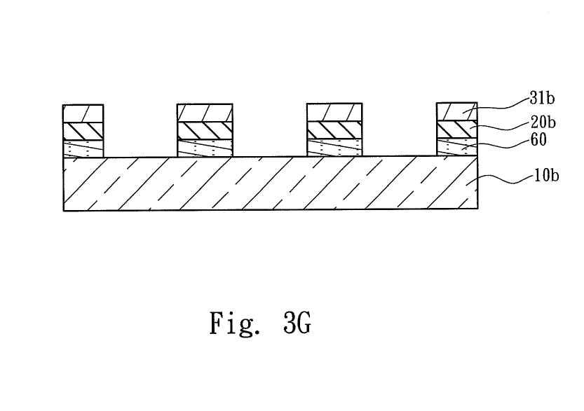

Refer to FIGS. 3A-3G sectional views schematically showing a patterned graphene fabrication method according a second embodiment of the present invention. Firstly, provide a substrate 10b. In this embodiment, the substrate 10b is made of a material miscible with carbon, such as iron, cobalt or nickel. Next, as shown in FIG. 3B, form an isolation layer 60 on the substrate 10b. The isolation layer 60 must be made of a material immiscible with carbon. In the present invention, the isolation layer 60 is preferably made of silicon dioxide, aluminum oxide or silicon carbide. Next, as shown in FIG. 3C, form a catalytic layer 20b on the substrate 10b. Similar to the first embodiment, the catalytic layer 20b is formed on the substrate 10b with an evaporation disposition process or a PVD process; the catalytic layer 20b is made of iron, cobalt, nickel, manganese, or an alloy of the abovementioned metals. Next, as shown in FIG. 3D, deposit a carbon layer 30b on the catalytic layer 20b with a deposition process. The deposition process may be realized with a spin-coating process, a sputtering process, or an evaporation disposition process. The carbon layer 30b is made of graphite or a carbon-containing polymer. The carbon-containing polymer is selected from a group consisting of acrylic resins, phenol formaldehyde resins, epoxy resins, and polymers containing long chains or hexagonal benzene rings.

After the carbon layer 30b has been formed on the catalytic layer 20b, photolithographically etch the carbon layer 30b. As shown in FIG. 3E, form a photoresist layer 40b on the carbon layer 30b firstly. Next, sequentially perform an exposure process and a development process on the photoresist layer 40b. As shown in FIG. 3F, place a photomask 50b over the photoresist layer 40b. In this embodiment, the photoresist layer 40b is made of a negative photoresist material; the photomask 50b is a perforated structure containing a light permeable area 52b and a light impermeable area 51b. The light impermeable area 51b defines at least one sacrifice area 41b in the photoresist layer 40b. The sacrifice area 41b is below the light impermeable area 51b and bordered by dashed lines in FIG. 3F. Light is projected on the photoresist layer 40b to enable the chemical reaction and cross link of the portion of photoresist layer 40b, which is below the light permeable area 52b. A development agent is used to dissolve and remove the portion of the photoresist layer 40b, which is below the light impermeable area 51b and not illuminated by light, i.e. remove the sacrifice areas 41b. Thus, a portion of the carbon layer 30a is revealed. Next, perform an etching process on the carbon layer 30b to remove a portion of the carbon layer 30b corresponding to the sacrifice areas 41b. The etching process may be a chemical etching process or a reactive ion etching (RIE) process. Next, remove the photomask 50b to obtain a patterned carbon layer 31b, as shown in FIG. 3G.

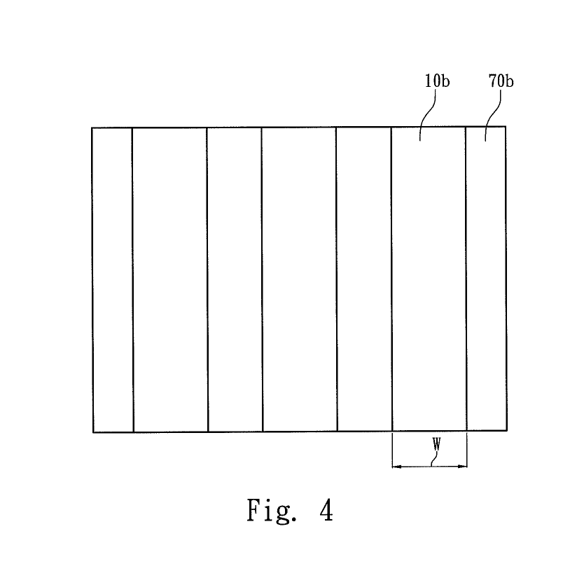

Then, heat the patterned carbon layer 31b to a synthesis temperature for a given interval of time to obtain a patterned graphene layer 70b. The synthesis temperature is preferably between 700 and 1,200° C. The patterned carbon layer 31b may be heated in vacuum or in an atmosphere of ammonia gas, argon, nitrogen, or a mixture of argon and hydrogen, a mixture of nitrogen and hydrogen. For the above mixtures, the volume concentration of hydrogen is preferably between 0 and 50%. In this embodiment, the given interval of time is preferably between 1 and 300 minutes. Refer to FIG. 4 a top view of the patterned graphene layer according to the second embodiment of the present invention. Preferably, each graphene structure of the patterned graphene layer 70b has a width of less than 7 μm. In this embodiment, the etching process simultaneously etches the carbon layer 30b, the catalytic layer 20b and the isolation layer 60. However, the etching process may only etch the carbon layer 30b or the carbon layer 30b plus the catalytic layer 20b in practical fabrication processes.

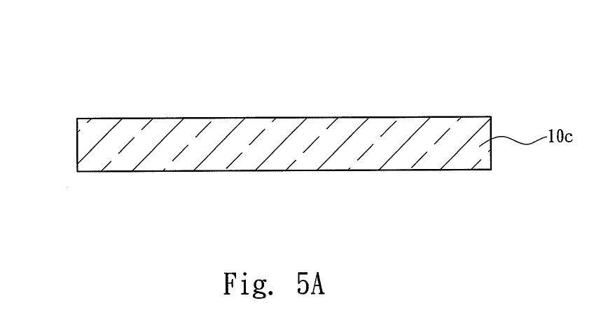

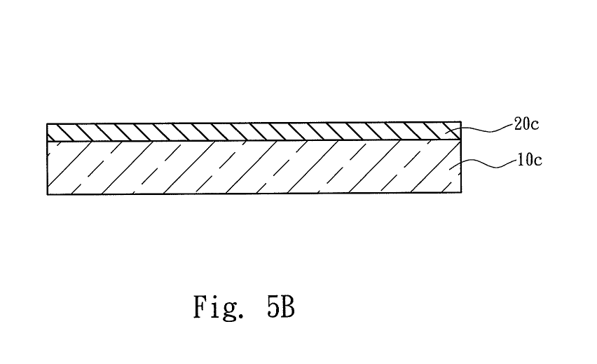

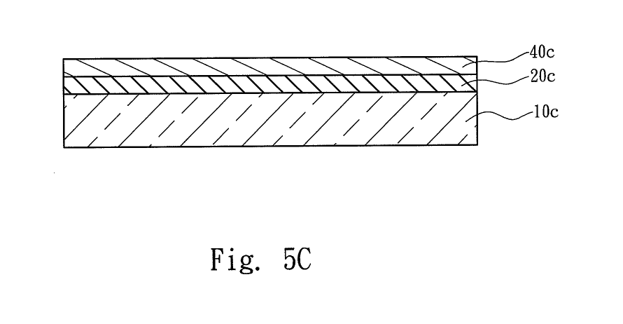

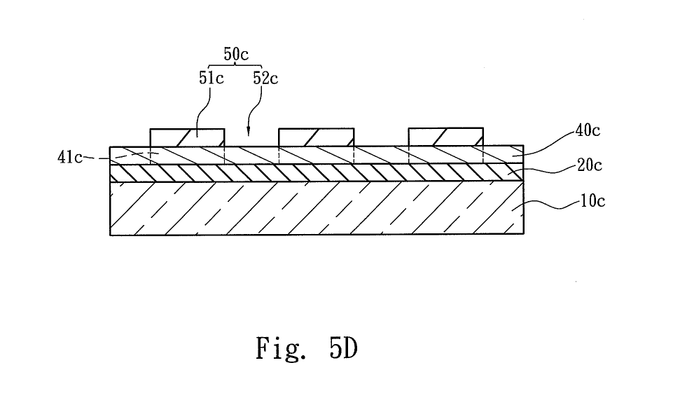

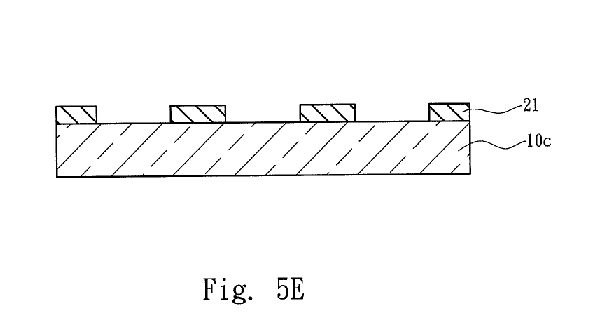

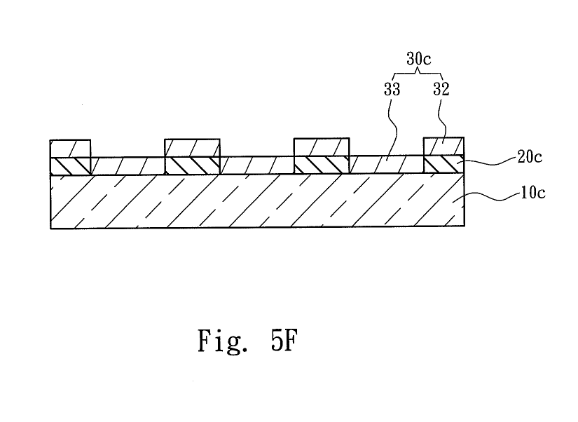

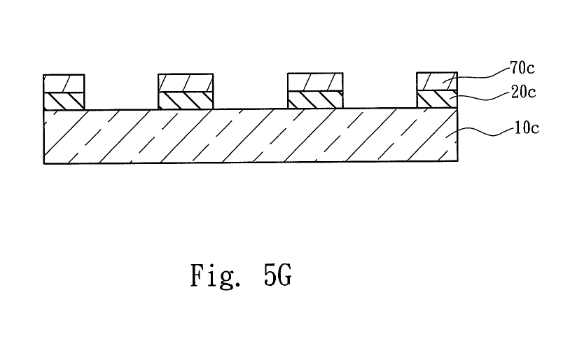

Refer to FIGS. 5A-5G sectional views schematically showing a patterned graphene fabrication method according a third embodiment of the present invention. Firstly, provide a substrate 10c. Next, as shown in FIG. 5B, form a catalytic layer 20c on the substrate 10c. Next, photo lithographically etch the catalytic layer 20c. As shown in FIG. 5C, form a photoresist layer 40c on the catalytic layer 20c firstly. Next, sequentially perform an exposure process and a development process on the photoresist layer 40c. As shown in FIG. 5D, place a photomask 50c over the photoresist layer 40c. In this embodiment, the photoresist layer 40c is made of a negative photoresist material; the photomask 50c is a perforated structure containing a light permeable area 52c and a light impermeable area 51c. The light impermeable area 51c defines at least one sacrifice area 41c in the photoresist layer 40c. The sacrifice area 41c is below the light impermeable area 51c and bordered by dashed lines in FIG. 5D.

Light is projected on the photoresist layer 40c to enable the chemical reaction and cross link of the portion of photoresist layer 40c, which is below the light permeable area 52c. A development agent is used to dissolve and remove the portion of the photoresist layer 40c, which is below the light impermeable area 51c and not illuminated by light, i.e. remove the sacrifice areas 41c. Thus, a portion of the catalytic layer 20c is revealed. Next, perform an etching process on the catalytic layer 20c to remove a portion of the catalytic layer 20c corresponding to the sacrifice areas 41c. The etching process may be a chemical etching process, a reactive ion etching (RIE) process, or another equivalent etching process having the same effect. Next, remove the photomask 50c to obtain a patterned catalytic layer 21, as shown in FIG. 5E.

Refer to FIG. 5F. After the photolithographic etching process is completed, form a carbon layer 30c on the catalytic layer 20c. The carbon layer 30c includes a patterned area 32 covering the patterned catalytic layer 21 and a non-patterned area 33 covering the substrate 10c. In this embodiment, the carbon layer 30c is made of graphite or a carbon-containing polymer. Then, heat the carbon layer 30c to a synthesis temperature for a given interval of time, whereby the patterned area 32 of the carbon layer 30c becomes a patterned graphene layer 70c, as shown in FIG. 5G. The synthesis temperature is preferably between 700 and 1,200° C. The carbon layer 30c may be heated in vacuum or in an atmosphere of ammonia gas, argon, nitrogen, or a mixture of argon and hydrogen, a mixture of nitrogen and hydrogen. For the above mixtures, the volume concentration of hydrogen is preferably between 0 and 50%. In this embodiment, the given interval of time is preferably between 1 and 300 minutes. According to requirement of practical fabrication, the non-patterned area 33 of the carbon layer 30c may be removed before or after heating. In this embodiment, the non-patterned area 33 is removed before the patterned area 32 becomes the patterned graphene layer 70c.

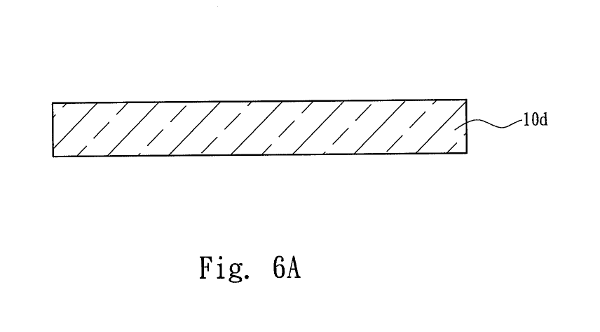

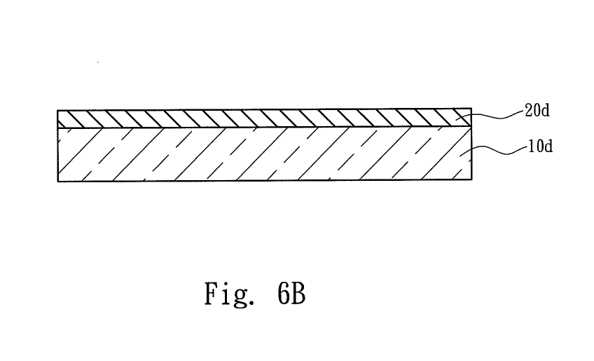

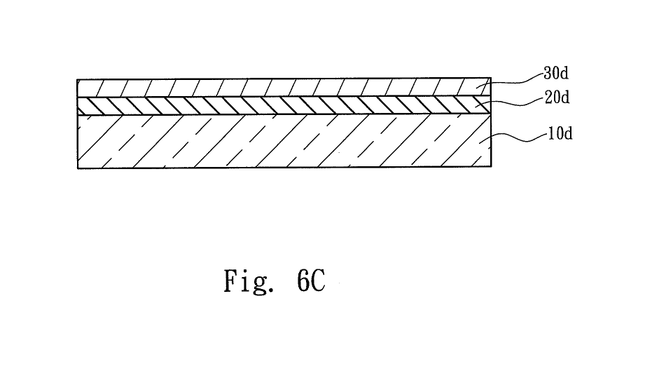

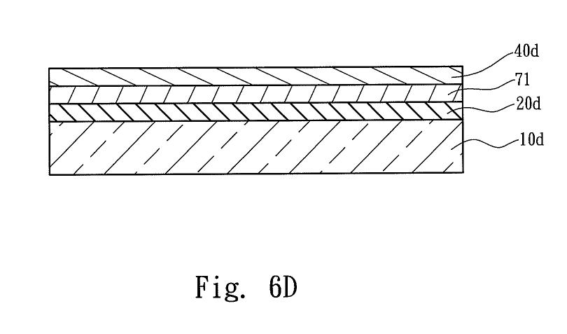

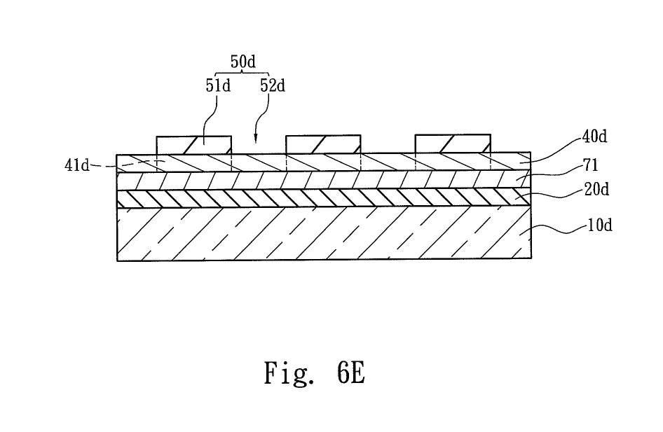

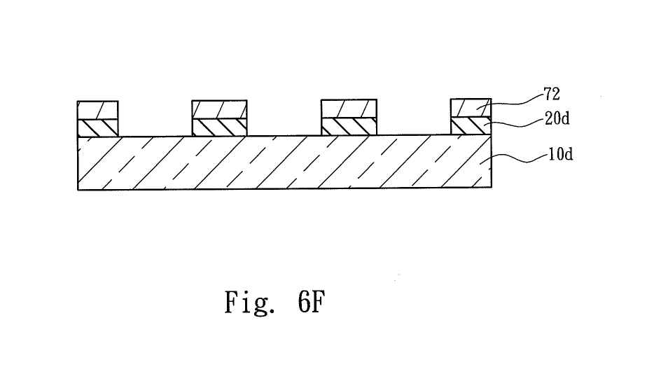

Refer to FIGS. 6A-6G sectional views schematically showing a patterned graphene fabrication method according a fourth embodiment of the present invention. Firstly, provide a substrate 10d. Next, as shown in FIG. 6B, form a catalytic layer 20d on the substrate 10d. Next, as shown in FIG. 6C, form a carbon layer 30d on the catalytic layer 20d. The carbon layer 30d is made of graphite or a carbon-containing polymer. The carbon-containing polymer is selected from a group of consisting of acrylic resins, phenol formaldehyde resins, epoxy resins, and polymers containing long chains or hexagonal benzene rings. After the carbon layer 30d has been formed on the catalytic layer 20d, heat the carbon layer 30d to a synthesis temperature for a given interval of time to obtain a graphene layer 71. The synthesis temperature is preferably between 700 and 1,200° C. The carbon layer 30d may be heated in vacuum or in an atmosphere of ammonia gas, argon, nitrogen, or a mixture of argon and hydrogen, a mixture of nitrogen and hydrogen. For the above mixtures, the volume concentration of hydrogen is preferably between 0 and 50%.

Next, photolithographically etch the graphene layer 71. As shown in FIG. 6D, form a photoresist layer 40d on the graphene layer 71 firstly. Next, sequentially perform an exposure process and a development process on the photoresist layer 40d. As shown in FIG. 6E, place a photomask 50d over the photoresist layer 40d. In this embodiment, the photoresist layer 40d is made of a negative photoresist material; the photomask 50d is a perforated structure containing a light permeable area 52d and a light impermeable area 51d. The light impermeable area 51d defines at least one sacrifice area 41d in the photoresist layer 40d. The sacrifice area 41d is below the light impermeable area 51d and bordered by dashed lines in FIG. 6E. Light is projected on the photoresist layer 40d to enable the chemical reaction and cross link of the portion of photoresist layer 40d, which is below the light permeable area 52d. A development agent is used to dissolve and remove the portion of the photoresist layer 40d, which is below the light impermeable area 51d and not illuminated by light, i.e. remove the sacrifice areas 41d. Thus, a portion of the graphene layer 71 is revealed. Next, perform an etching process on the graphene layer 71 to remove a portion of the graphene layer 71 corresponding to the sacrifice areas 41d. The etching process may be a chemical etching process or a reactive ion etching (RIE) process. Next, remove the photomask 50d, and use an appropriate solvent to dissolve the negative photoresist material. Thus is obtained a patterned graphene layer 72, as shown in FIG. 6F.

In the third and fourth embodiments, the substrates 10c and 10d are made of a material immiscible with carbon; the substrates 10c and 10d may be made of a metal or a ceramic material, such as copper, aluminum, silicon dioxide, aluminum oxide, or silicon carbide. In the third and fourth embodiments, the catalytic layers 20c and 20d are formed with an evaporation disposition process or a PVD process; the catalytic layers 20c and 20d are made of iron, cobalt, nickel, manganese, or an alloy of the above-mentioned metals. In the third and fourth embodiments, the carbon layers 30c and 30d are formed on the catalytic layers 20c and 20d with a deposition process; the deposition process may be a spin-coating process, a sputtering process, or an evaporation deposition process. In the third and fourth embodiments, the substrates 10c and 10d may be alternatively made of a material miscible with carbon, such as iron, cobalt or nickel, and an isolation layer made of a material immiscible with carbon is formed on the substrates 10c and 10d before formation of the catalytic layers 20c and 20d.

In the abovementioned embodiments, the patterned graphene strictures are in form of a plurality of parallel strip-like structures. However, the present invention does not constrain that the patterned graphene structures must be in form of parallel strips. In the present invention, the graphene structure may be in form of an arbitrary geometrical shape, such as a triangle, a rectangle, etc. In the abovementioned embodiments, the photoresist layers 40a, 40b, 40c and 40d are made of a negative photoresist material. However, the photoresist layers 40a, 40b, 40c and 40d may be alternatively made of a positive photoresist material if it is required in practical fabrication.

In conclusion, the present invention patterns the carbon layer or the graphene layer with a photolithographic etching technology. If the carbon layer is photolithographically etched into a patterned carbon layer before graphene synthesis, the patterned carbon layer is converted into patterned graphene structures. The photolithographic etching technology is far more efficient than the laser etch technology. Therefore, the present invention has productivity much higher than that of the laser etch-based conventional technology. Further, the present invention is suitable to fabricate large-size patterned graphene structures. Besides, the apparatuses of the photolithographic etching process are easy to acquire with a lower cost in comparison with the apparatuses of the laser etching process. Therefore, the present invention also has advantages of simple fabrication processes and high cost efficiency. Hence, the present invention possesses utility, novelty and non-obviousness and meets the condition for a patent. Thus, the Inventors file the application for a patent. It is appreciated if the patent is approved fast.

The embodiments described above are only to exemplify the present invention but not to limit the scope of the present invention. Any equivalent modification or variation according to the spirit of the present invention is to be also included within the scope of the present invention, which is based on the claims stated below.

What is claimed is:

1. A patterned graphene fabrication method, comprising:
providing a substrate;
forming a catalytic layer on the substrate;
forming a carbon layer on the catalytic layer;
performing a photolithographic etching process on the carbon layer to form a patterned carbon layer; and
heating the patterned carbon layer to a synthesis temperature to form a patterned graphene layer.

2. The patterned graphene fabrication method according to claim 1, wherein an isolation layer made of a material immiscible with carbon is formed on the substrate before formation of the catalytic layer.

3. The patterned graphene fabrication method according to claim 2, wherein the isolation layer is made of a material selected from a group consisting of silicon dioxide, aluminum oxide and silicon carbide.

4. The patterned graphene fabrication method according to claim 1, wherein the catalytic layer is made of a material selected from a group consisting of iron, cobalt, nickel and manganese.

5. The patterned graphene fabrication method according to claim 1, wherein the carbon layer is formed on the catalytic layer with a deposition method, and wherein the deposition process is selected from a group consisting of a spin-coating process, a sputtering process, and an evaporation disposition process.

6. The patterned graphene fabrication method according to claim 1, wherein the catalytic layer is formed on the substrate with an evaporation disposition process or a physical vapor deposition process.

7. The patterned graphene fabrication method according to claim 1, wherein the synthesis temperature is between 700 and 1,200° C.

8. The patterned graphene fabrication method according to claim 1, wherein the carbon layer is made of graphite or a carbon-containing polymer.

9. The patterned graphene fabrication method according to claim 1, wherein the photolithographic etching process includes:
forming a photoresist layer on the carbon layer, wherein the photoresist layer includes at least one sacrifice area;
removing the sacrifice area to reveal a portion of the carbon layer; and
performing an etching process on the carbon layer to remove the revealed carbon layer and obtain the patterned carbon layer.

10. The patterned graphene fabrication method according to claim 9, wherein the etching process is a chemical etching process or a reactive ion etching process.

11. A patterned graphene fabrication method comprising
providing a substrate;
forming a catalytic layer on the substrate;
performing a photolithographic etching process on the catalytic layer to form a patterned catalytic layer;
forming on the patterned catalytic layer a carbon layer including a patterned area covering the patterned catalytic layer and a non-patterned area covering the substrate; and
heating the carbon layer to a synthesis temperature to convert the patterned area of the carbon layer into a patterned graphene layer.

12. The patterned graphene fabrication method according to claim 11, wherein an isolation layer made of a material immiscible with carbon is formed on the substrate before formation of the catalytic layer.

13. The patterned graphene fabrication method according to claim 12, wherein the isolation layer is made of a material selected from a group consisting of silicon dioxide, aluminum oxide, and silicon carbide.

14. The patterned graphene fabrication method according to claim 11, wherein the catalytic layer is made of a material selected from a group consisting of iron, cobalt, nickel and manganese.

15. The patterned graphene fabrication method according to claim 11, wherein the carbon layer is formed on the catalytic layer with a deposition process, and wherein the deposition process is selected from a group consisting of a spin-coating process, a sputtering process, and an evaporation disposition process.

16. The patterned graphene fabrication method according to claim 11, wherein the catalytic layer is formed on the substrate with an evaporation disposition process or a physical vapor deposition process.

17. The patterned graphene fabrication method according to claim 11, wherein the synthesis temperature is between 700 and 1,200° C.

18. The patterned graphene fabrication method according to claim 11, wherein the carbon layer is made of graphite or a carbon-containing polymer.

19. The patterned graphene fabrication method according to claim 11, wherein the photolithographic etching process includes
forming a photoresist layer on the catalytic layer, wherein the photoresist layer includes at least one sacrifice area;
removing the sacrifice area to reveal a portion of the catalytic layer; and
performing an etching process on the catalytic layer to remove the revealed catalytic layer and obtain the patterned catalytic layer.

20. The patterned graphene fabrication method according to claim 19, wherein the etching process is a chemical etching process or a reactive ion etching process.

21. A patterned graphene fabrication method, comprising:
providing a substrate;
forming a catalytic layer on the substrate;
forming a carbon layer on the catalytic layer;
heating the carbon layer to a synthesis temperature to obtain a graphene layer; and
performing a photolithographic etching process on the graphene layer to obtain a patterned graphene layer.

22. The patterned graphene fabrication method according to claim 21, wherein an isolation layer made of a material immiscible with carbon is formed on the substrate before formation of the catalytic layer.

23. The patterned graphene fabrication method according to claim 21, wherein the isolation layer is made of a material selected from a group consisting of silicon dioxide, aluminum oxide, and silicon carbide.

24. The patterned graphene fabrication method according to claim 21, wherein the catalytic layer is made of a material selected from a group consisting of iron, cobalt, nickel and manganese.

25. The patterned graphene fabrication method according to claim 21, wherein the carbon layer is formed on the catalytic layer with a deposition process, and wherein the deposition process is selected from a group consisting of a spin-coating process, a sputtering process, and an evaporation disposition process.

26. The patterned graphene fabrication method according to claim 21, wherein the catalytic layer is formed on the substrate with an evaporation disposition process or a physical vapor deposition process.

27. The patterned graphene fabrication method according to claim 21, wherein the synthesis temperature is between 700 and 1,200° C.

28. The patterned graphene fabrication method according to claim 21, wherein the carbon layer is made of graphite or a carbon-containing polymer.

29. The patterned graphene fabrication method according to claim 21, wherein the photolithographic etching process includes:
forming a photoresist layer on the graphene layer, wherein the photoresist layer includes at least one sacrifice area;
removing the sacrifice area to reveal a portion of the graphene layer; and
performing an etching process on the graphene layer to remove the revealed graphene layer and obtain the patterned graphene layer.

30. The patterned graphene fabrication method according to claim 29, wherein the etching process is a chemical etching process or a reactive ion etching process.
